(19) United States
(12) Patent Application Publication
(10) Pub. No.: US 2026/0265954 A1
(43) Pub. Date: Sep. 10, 2026

(54) CYLINDRICAL DEVICE, METHOD OF PRODUCING CYLINDRICAL DEVICE, AND METHOD OF CRYSTALLIZING PROTEIN

(71) Applicant: TANAKA PRECIOUS METAL GROUP Co., Ltd., Tokyo (JP)

(72) Inventor: Masahiro ITO, Tokyo (JP)

(73) Assignee: TANAKA PRECIOUS METAL GROUP Co., Ltd., Tokyo (JP)

(21) Appl. No.: 19/468,144

(22) Filed: Feb. 3, 2026

(30) Foreign Application Priority Data
Mar. 6, 2025 (JP) 2025-035918

(51) Int. Cl. C30B 35/00; C30B 7/00; C30B 29/58

(52) U.S. Cl. CPC C30B 35/002; C30B 7/00; C30B 29/58

(57) ABSTRACT

Provided are a cylindrical device in which crystallization by a counter-diffusion method is facilitated, a method of producing the cylindrical device, and a method of crystallizing a protein using the cylindrical device. The cylindrical device includes a cylindrical body that has a long shape; and a metal structure disposed on an inner surface of the cylindrical body. The metal structure includes metal particles arranged on the inner surface of the cylindrical body. The metal particles have an average value of diameter of 5 nm or more and 50 nm or less when viewed in a direction perpendicular to the inner surface of the cylindrical body. An average value of interparticle surface distance between adjacent metal particles is 3 nm or more and 90 nm or less.

### CROSS-REFERENCE TO RELATED APPLICATION

This application claims priority based on Japanese Patent Application No. 2025-035918, filed Mar. 6, 2025, the entire content of which is incorporated herein by reference.

### TECHNICAL FIELD

The present disclosure relates to a cylindrical device, a method of producing a cylindrical device, and a method of crystallizing a protein.

### BACKGROUND

Patent Literature (PTL) 1 describes a nanostructure substrate. This nanostructure substrate is composed of a metal structure made of a composite particle group and a substrate made of a resin base and a support, and has a front and back surface. This nanostructure substrate has a larger geometric surface area on the front side of the composite particle group than on the back side, and the composite particles are composed of metal or other fine particles with a coating layer of metal or co-deposited material precipitated thereon by reduction, with the lower parts of the metal or other fine particles embedded in the resin base, and the embedded metal or other fine particles being spaced apart from each other. It is described that in this nanostructure substrate, the composite particle group exhibits plasmonic properties.

PTL 2 describes a method of concentrating and crystallizing biopolymers and a nanostructure substrate. PTL 2 describes an example of a method of crystallizing a biopolymer, in which reduced gold nanoparticles (average particle size 20 nm) are self-assembled on a transparent polyester resin film and half-submerged to fix them. This substrate is repeatedly immersed in an electroless gold plating solution to precipitate gold particles on the gold nanoparticles, and 10 microliters of a protein solution is dropped onto this nanostructure substrate and crystallized by a hanging drop vapor diffusion method.

Non-Patent Literature (NPL) 1 describes a crystallization method called a counter-diffusion method.

The counter-diffusion method described in NPL 1 is used for crystallization of a crystallization target (a substance to be crystallized) such as a protein.

Taking the case where the crystallization target is a protein as an example, crystallization can be attempted in the counter-diffusion method as follows. First, a protein solution (crystallization target solution) is filled into a capillary (cylindrical device) such as a thin glass tube, and the lower end of the capillary is closed with a porous body (gel-like substance, hereinafter referred to as a gel layer). Then, the lower end of the capillary is immersed in a precipitant solution (a solution of a substance that promotes crystallization of the crystallization target).

The protein solution then diffuses from inside the capillary to the outside through the gel layer, and the precipitant solution diffuses through the gel layer into the capillary. When the protein solution and the precipitant solution mutually diffuse in this way, convection in the liquid is suppressed within the thin capillary. This results in gradients of various protein concentrations and precipitant solution concentrations in the capillary, which also change over time. This allows the counter-diffusion method to experiment with a wide range of conditions at once within a single capillary, making it easier to successfully crystallize crystallization targets that are typically considered difficult to crystallize.

In this way, the counter-diffusion method allows experiments under a wide range of conditions to be conducted simultaneously within a single capillary, and has the advantage of being more likely to successfully crystallize crystallization targets that are typically considered difficult to crystallize. Therefore, it is suitable for crystallization experiments on substances such as proteins, which are generally known to be difficult to crystallize.

Further, while taking advantage of the characteristic that convection in liquids is suppressed within a thin capillary, crystallization is sometimes attempted in microgravity environments such as those found in outer space, in order to eliminate the effects of gravity.

NPL 2 has a general explanation of Voronoi diagrams and sites and Voronoi regions in Voronoi diagrams, and the like.

### CITATION LIST

### Patent Literature

PTL 1: JP 2020-180091 A
PTL 2: JP 2020-180356 A

### Non-Patent Literature

NPL 1: Sano et al., “The Key Technology of the Protein Crystallization in Space”, Journal of the Japan Society for Microgravity Application, Vol. 25, No. 2, 2008, pp. 157-160
NPL 2: “Voronoi diagram”, Wikipedia, [Retrieved Jan. 6, 2025], the Internet: https://en.wikipedia.org/wiki/Voronoi_diagram

### SUMMARY

### Technical Problem

As mentioned above, counter-diffusion methods are often used for substances that are difficult to crystallize and are often used in costly environments such as outer space. Therefore, there is a need for a method that will make it easier to achieve successful crystallization (increase the probability of successful crystallization) in a counter-diffusion method.

The present disclosure is made in consideration of the circumstances described above, and it would be helpful to provide a cylindrical device that facilitates crystallization by a counter-diffusion method, a method of producing the cylindrical device, and a method of crystallizing proteins using the cylindrical device.

### Solution to Problem

The cylindrical device according to the present disclosure comprises:
a cylindrical body that has a long shape; and
a metal structure disposed on an inner surface of the cylindrical body, wherein
the metal structure includes metal particles arranged on the inner surface of the cylindrical body,
the metal particles have an average value of diameter of 5 nm or more and 50 nm or less when viewed in a direction perpendicular to the inner surface of the cylindrical body, and
an average value of interparticle surface distance between adjacent metal particles is 3 nm or more and 90 nm or less.

A method of producing a cylindrical device according to the present disclosure is
a method of producing the cylindrical device described above, the method comprising:
a primer layer forming process of forming a primer layer containing methylol melamine or a methylol melamine derivative on the inner surface of the cylindrical body; and
a metal structure forming process of constructing the metal structure on the primer layer, wherein
the metal structure forming process includes a liquid contact process of maintaining a state in which a metal colloid solution is retained within the cylindrical body.

A method of crystallizing a protein according to the present disclosure is
a method of crystallizing a protein by a counter-diffusion method, comprising:
using the cylindrical device described above as a capillary.

### Advantageous Effect

According to the present disclosure, it is possible to provide a cylindrical device in which crystallization by a counter-diffusion method is facilitated, a method of producing the cylindrical device, and a method of crystallizing a protein using the cylindrical device.

### BRIEF DESCRIPTION OF THE DRAWINGS

In the accompanying drawings:

FIG. 1 is a perspective view diagram of a cylindrical device;

FIG. 2 is a schematic cross-section diagram of a cylindrical device;

FIG. 3 is a schematic diagram illustrating a state in which a portion of an inner surface of a cylindrical device is developed into a flat surface;

FIG. 4 is an SEM image of point A in Example 1;

FIG. 5 is an SEM image of point B in Example 1;

FIG. 6 is an SEM image of point C in Example 1;

FIG. 7 is a Voronoi analysis diagram of point A in Example 1;

FIG. 8 is an explanatory diagram of a protein crystallization experiment using a counter-diffusion method;

FIG. 9 is an SEM image of point A in Example 2;

FIG. 10 is an SEM image of point B in Example 2; and

FIG. 11 is an SEM image of point C in Example 2.

### DETAILED DESCRIPTION

A cylindrical device, a method of producing a cylindrical device, and a method of crystallizing a protein according to embodiments of the present disclosure are described, with reference to the drawings.

First, outlines of a cylindrical device, a method of producing a cylindrical device, and a method of crystallizing a protein according to embodiments of the present disclosure are described.

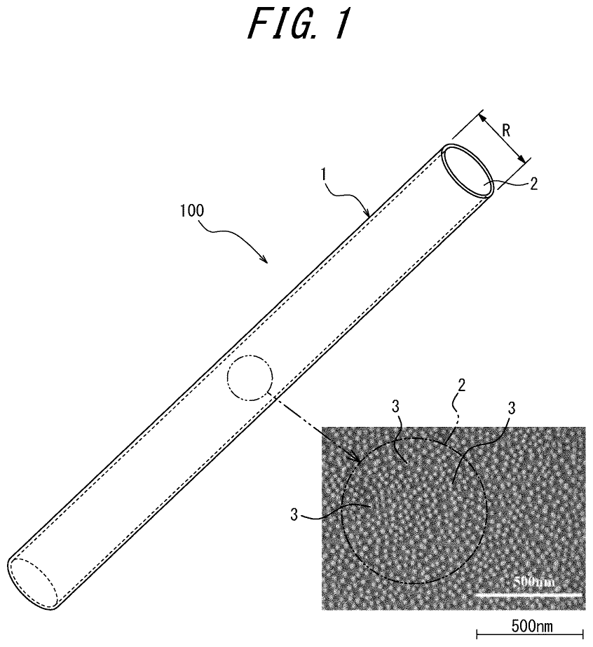

FIG. 1 illustrates a cylindrical device 100 according to an embodiment.

The cylindrical device 100 comprises a cylindrical body 1 that has a long shape; and a metal structure 2 disposed on an inner surface of the cylindrical body 1. The metal structure 2 includes metal particles 3 arranged on the inner surface of the cylindrical body 1. The metal particles 3 have an average value of diameter of 5 nm or more and 50 nm or less when viewed in a direction perpendicular to the inner surface of the cylindrical body 1. An average value of interparticle surface distance between adjacent metal particles 3,3 is 3 nm or more and 90 nm or less.

By using the cylindrical device 100 as a capillary, crystallization by a counter-diffusion method is facilitated. In other words, the cylindrical device 100 is suitable for use as a capillary in a counter-diffusion method.

A method of protein crystallization according to an embodiment can be carried out by using the cylindrical device 100 as a capillary in a counter-diffusion method.

A method of producing a cylindrical device according to an embodiment comprises: a primer layer forming process of forming a primer layer 21 containing methylol melamine or a methylol melamine derivative on the inner surface of a cylindrical body 1; and a metal structure forming process of constructing the metal structure 2 on the primer layer 21. The metal structure forming process includes a liquid contact process of maintaining a state in which a metal colloid solution is retained within the cylindrical body 1.

The cylindrical device 100 may be produced by the method of producing a cylindrical device according to this embodiment.

The cylindrical device 100 is described in detail below.

The cylindrical body 1 is a cylinder or cylindrical member that has a long shape. The metal structure 2 is disposed on the inner surface of the cylindrical body 1.

The cylindrical body 1 may be formed of, for example, glass, polycarbonate, acrylic, acrylonitrile butadiene styrene polyimide, polyethylene terephthalate, polystyrene, or cycloolefin polymer. The cylindrical body 1 is preferably made of glass.

An inner diameter of the cylindrical body 1 is, for example, 0.2 mm or more and 2 mm or less.

The length of the cylindrical body 1 in the longitudinal direction of the cylinder (the same as the axial direction of the cylinder) is, for example, 50 mm or more and 300 mm or less.

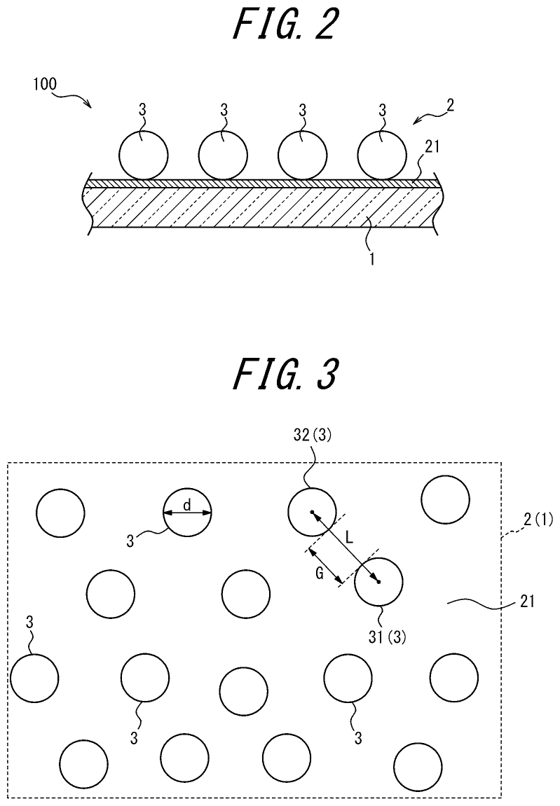

As illustrated in FIG. 2 and FIG. 3, the metal structure 2 is a structural portion formed on the inner surface of the cylindrical body 1 (the inner surface of the tube of the cylindrical body 1), and is a structural portion having an arrangement structure of the metal particles 3 arranged on the inner surface of the cylindrical body 1. The metal structure 2 has a plurality (a large number) of the metal particles 3 arranged on the inner surface of the cylindrical body 1. FIG. 2 is a schematic cross-section diagram of the cylindrical device 100. FIG. 3 is a schematic diagram illustrating a state in which part of the inner surface of the cylindrical device 100 (see FIG. 1) is developed into a flat surface.

The metal structure 2 may include the primer layer 21 formed on the inner surface of the cylindrical body 1. The primer layer 21 is preferably a layer containing methylol melamine or a methylol melamine derivative. When the metal structure 2 includes the primer layer 21, the metal particles 3 may be fixed onto the inner surface of the cylindrical body 1 via the primer layer 21.

The metal particles 3 are metal nanoparticles. The metal particles 3 are preferably nanoparticles of an element from group IB or group VIIIB of the periodic table. Specifically, gold (Au), silver (Ag), copper (Cu), platinum (Pt), palladium (Pd), rhodium (Rh), iridium (Ir), ruthenium (Ru), nickel (Ni), cobalt (Co), or iron (Fe). In particular, the metal particles 3 are preferably colloidal nanoparticles of gold (Au), silver (Ag), or palladium (Pd).

The metal particles 3 preferably have a diameter of 5 nm or more and 50 nm or less when viewed in a direction perpendicular to the inner surface of the cylindrical body 1. In this case, the diameter refers to a circle equivalent diameter calculated based on a projected area of the metal particles 3 when viewed in a direction perpendicular to the inner surface of the cylindrical body 1 (the diameter of a circle having the same area as the projected area). When the metal particles 3 have such a diameter, surface plasmon resonance occurs in the vicinity of the surfaces of the metal particles 3. As a result, when the cylindrical device 100 is used as a capillary (a thin tube that holds a solution of a crystallization target, such as a protein) for a counter-diffusion method, crystals of the crystallization target are more likely to form in the vicinity of the metal particles 3.

An average value (arithmetic mean value) of diameter of the metal particles 3 is preferably 5 nm or more and 50 nm or less. When the average value of diameter of the metal particles 3 is in this range, surface plasmon resonance occurs more easily in the vicinity of the surface of the metal particles 3. Hereinafter, the average value of diameter of the metal particles 3 is referred to simply as the average value of particle size.

The circle equivalent diameter of the metal particles 3 may be determined by image analysis using an electron microscope image (SEM image) of the metal structure 2. When determining the circle equivalent diameter of the metal particles 3, an SEM image taken with a field emission scanning electron microscope (produced by Hitachi High-Tech Corporation, model: SU8000) may be used as the image of the measurement target. The SEM image may be an image taken at a magnification of 100,000 times.

The metal particles 3 preferably have an average particle size of 5 nm or more and 50 nm or less in the state of the metal colloid solution used in the metal structure forming process. The average particle size of the metal particles 3 according to the present embodiment is a volume-based average particle size measured using a particle size measuring system (produced by Otsuka Electronics Co., Ltd., model: ELSZ1000) using dynamic light scattering (DLS). When the metal particles 3 have such a diameter, and when the metal structure 2 is formed by the method of producing a cylindrical device described below, the diameter of the metal particles 3 of the formed metal structure 2 when viewed in a direction perpendicular to the inner surface of the cylindrical body 1 can be made 5 nm or more and 50 nm or less.

An average value of interparticle distance L between adjacent metal particles 3,3 is preferably 8 nm or more and 140 nm or less. This makes it easier for crystals of the crystallization target to form between the metal particles 3,3.

According to the present embodiment, the average value of the interparticle distance L is a value determined by dividing the area of the image to be measured into Voronoi regions using the center of gravity of each of the metal particles 3 in the image as a site, calculating the average value (arithmetic mean value) of the areas of the Voronoi regions containing the center of gravity of each metal particle 3, and then calculating the square root of this average value of area.

When determining the average value of the interparticle distance L, an SEM image taken with a field emission scanning electron microscope (produced by Hitachi High-Tech Corporation, model: SU8000) may be used as the image of the measurement target. The SEM image may be an image taken at a magnification of 100,000 times.

According to the present embodiment, the average value of an interparticle surface distance G between adjacent metal particles 3,3 is a value determined by subtracting the average value of the particle size of the metal particles 3 from the average value of the interparticle distance L. The interparticle surface distance G is the so-called interparticle gap.

The average value of the interparticle surface distance G is 3 nm or more and 90 nm or less. This makes it easier for surface plasmon resonance to occur in the vicinity of the surface of the metal particles 3, particularly between the metal particles 3,3, and when the cylindrical device 100 is used as a capillary (a narrow tube that holds a solution of a crystallization target such as a protein) for a counter-diffusion method, crystals of the crystallization target are more likely to form between the metal particles 3,3.

When the metal structure 2 is divided into Voronoi regions using the center of gravity of each of the metal particles 3 as a site, an average value (arithmetic mean value) of the areas of these Voronoi regions is preferably 1000 nm² or more and 4000 nm² or less, and more preferably 1000 nm² or more and 3000 nm² or less. This makes it even easier for surface plasmon resonance to occur in the vicinity of the surface of the metal particles 3, particularly between the metal particles 3,3, and when the cylindrical device 100 is used as a capillary (a narrow tube that holds a solution of a crystallization target such as a protein) for a counter-diffusion method, crystals of the crystallization target are even more likely to form between the metal particles 3,3. Specifically, when the area in the image to be measured is divided into Voronoi regions using the center of gravity of each of the metal particles 3 in the image as a site, the average value of the areas of the Voronoi regions in the image of the metal structure 2 is preferably 1000 nm² or more and 4000 nm² or less, and more preferably 1000 nm² or more and 3000 nm² or less.

When the metal structure 2 is divided into Voronoi regions using the center of gravity of each of the metal particles 3 as a site, the standard deviation of the areas of these Voronoi regions is preferably 200 nm² or more and 2200 nm² or less, and more preferably 200 nm² or more and 2000 nm² or less. This makes it easier for surface plasmon resonance to occur uniformly in the vicinity of the surface of the metal particles 3, particularly between the metal particles 3,3, and when the cylindrical device 100 is used as a capillary (a narrow tube that holds a solution of a crystallization target such as a protein) for a counter-diffusion method, crystals of the crystallization target are even more likely to form between the metal particles 3,3.

The method of producing a cylindrical device is described in detail below.

The primer layer forming process is a process of forming a primer layer containing methylol melamine or a methylol melamine derivative on the inner surface of the cylindrical body.

As the methylol melamine derivative, examples include a methylol melamine derivative obtained by condensing melamine and formaldehyde, a partially or completely etherified compound obtained by reacting methylol melamine with a lower alcohol, a mixture of these, and the like. As the lower alcohol, examples include an aliphatic alcohol having 1 to 4 carbon atoms.

The methylol melamine derivative may be any of a condensate of a monomer or a dimer or higher polymer of methylol melamine or a methylol melamine derivative, or a mixture thereof. An example of a methylol melamine derivative monomer is alkylated melamine such an as hexamethoxymethylmelamine. Examples of condensates consisting of polymers of methylol melamine derivatives include imino group-type methylated melamine resins, methylol group-type methylated melamine resins, and fully alkylated methylated melamine resins.

An example of a method of forming a primer layer on the inner surface of the cylindrical body 1 is as follows.

One example of a method of forming a primer layer on the inner surface of the cylindrical body 1 is to prepare a primer solution containing methylol melamine or a methylol melamine derivative (hereinafter sometimes referred to as a primer) and pass this through the inside of the cylindrical body 1. In this method, a primer solution is passed through the inside of the cylindrical body 1, thereby allowing the primer to adhere to the inner surface of the cylindrical body 1.

After the primer is applied to the inner surface of the cylindrical body 1, excess primer solution is removed from inside the cylindrical body 1, and then the primer layer can be formed by heating and drying in an oven or the like for a defined time (for example, 5 min to 20 min) at a defined temperature (for example, 150° C. to 200° C.).

The primer solution may contain a base resin for fixing the primer to the inner surface of the cylindrical body 1 and an acid catalyst for crosslinking and curing (thermosetting) the primer and base resin. Further, the primer solution may contain an organic solvent such as cyclohexane.

An example of the base resin is a thermoplastic saturated polyester.

As the acid catalyst, examples include a sulfonic acid-based acid catalyst or a phosphoric acid-based acid catalyst. For example, a dinonylnaphthalene disulfonic acid catalyst, a dinonylnaphthalene sulfonic acid catalyst, a p-toluenesulfonic acid, a pyridine paratoluenesulfonic acid, or a blocked acid catalyst of any of these and a blocked acid catalyst of phosphoric acid can be used.

The metal structure forming process is a process of constructing the metal structure 2 on the primer layer 21. The metal structure forming process includes a liquid contact process in which a metal colloid solution such as a gold colloid solution is maintained in the cylindrical body 1.

The metal colloid solution may be a colloid solution of gold (Au), silver (Ag), copper (Cu), platinum (Pt), palladium (Pd), rhodium (Rh), iridium (Ir), ruthenium (Ru), nickel (Ni), cobalt (Co), or iron (Fe).

In the liquid contact process, the metal colloid solution is injected into the cylindrical body 1, and the cylindrical body 1 is filled with the metal colloid solution and maintained (left to stand) for 2 min to 20 min (for example, 10 minutes). In other words, the metal particles 3 are thereby captured by the methylol groups of the primer layer 21, and the metal structure 2 is formed on the primer layer 21.

In the liquid contact process, it is preferable to perform the operation of filling and retaining the metal colloid solution inside the cylindrical body 1 (maintaining the metal colloid solution in a state where it remains inside the cylindrical body 1) two or more times (for example, three times). That is, in the liquid contact process, the metal colloid solution held in the cylindrical body 1 may be replaced one or more times (for example, twice). This allows the metal structure 2 to be formed uniformly along the axial direction of the cylindrical body 1. In the liquid contact process, the total time (that is, residence time) that the inside of the cylindrical body 1 is filled with the metal colloid solution is 5 min or more and 60 min or less, and preferably 15 min or more and 60 min or less.

The liquid contact process is preferably carried out under temperature control. For example, the liquid passing step may be carried out at a temperature of 15° C. or higher and 30° C. or lower, and preferably 20° C. or higher and 28° C. or lower. This allows the metal structure 2 to be formed uniformly over the entire inner surface of the cylindrical body 1.

### EXAMPLES

The following describes, based on examples, the cylindrical device, the method of producing the cylindrical device, and the method of crystallizing a protein using the cylindrical device according to embodiments.

### Example 1

According to this example, a primer solution and a gold colloid solution were prepared as follows, and a cylindrical device was produced by forming a metal structure having gold nanoparticles arranged on the inner surface of a glass tube as the cylindrical body that has a long shape. This cylindrical device was then used as a capillary in a counter-diffusion method to conduct protein crystallization experiments.

The primer solution was prepared as follows. A primer solution according to this example was prepared by dissolving 0.8 wt % of a methylol melamine crosslinking agent (product name: CYMEL303LF, produced by Allnex GmbH, containing 99 wt % or more of alkylated melamine as the main component), 0.2 wt % of pyridine paratoluenesulfonic acid, and 2.5 wt % of a thermoplastic saturated polyester in cyclohexane as a solvent.

The gold colloid solution was prepared as follows. A first solution was prepared by dissolving 0.3 g/L of tetrachloroauric (III) acid and 1.0 g/L of trisodium citrate dihydrate in ultrapure water as a solvent. Then, an appropriate amount of sodium hydroxide was added to the first solution to adjust the pH to 11 to prepare a second solution. The second solution was heated and stirred at 95° C. for 30 min in a round-bottom flask to obtain a colloidal solution containing gold nanoparticles having an average particle size of 20 nm, which was used as the gold colloidal solution of the present example. The average particle size of the gold nanoparticles in the gold colloid solution is a volume-based average particle size measured using a particle size measurement system (produced by Otsuka Electronics Co., Ltd., model: ELSZ1000) using dynamic light scattering (DLS).

A clean glass tube having an inner diameter of 0.5 mm and a length of 15 cm was prepared.

A primer layer was formed on the glass tube as follows.

First, a primer solution was poured into the glass tube to fill the tube (cylinder), and after the primer solution was brought into contact with the entire surface of the inside of the glass tube, the primer solution was allowed to flow out of the glass tube. Then, cleaning gas (air) was blown into the glass tube using an air gun to expel excess primer solution remaining in the glass tube. Thereafter, the glass tube was placed in a forced circulation oven under atmospheric pressure and heated and dried to form a primer layer. The temperature inside the oven was set to 180° C. The heating and drying time (the time during which the glass tube was placed in the oven) was 15 min. The glass tube was placed upright in the oven.

A metal structure in which gold nanoparticles were arranged was formed on the glass tube on which the primer layer was formed (hereinafter simply referred to as the glass tube) in the following way.

First, a gold colloid solution was injected into the glass tube, filling the glass tube (but only the portion where the metal structure was to be formed) with the gold colloid solution. Next, the glass tube was held under temperature control for 10 min while maintaining the gold colloid solution in a state where it remained inside the glass tube. Thereafter, the gold colloid solution was allowed to flow out of the glass tube. This series of operations (hereinafter referred to as the replacement operation) was repeated three times to form the metal structure. After the gold colloid solution was injected to fill the glass tube, the temperature of the glass tube was controlled at 25±3° C. Thereafter, the inside of the glass tube was washed with ultrapure water, and clean gas (air) was blown into the glass tube to dry the inside of the glass tube, thereby producing the cylindrical device according to the present example.

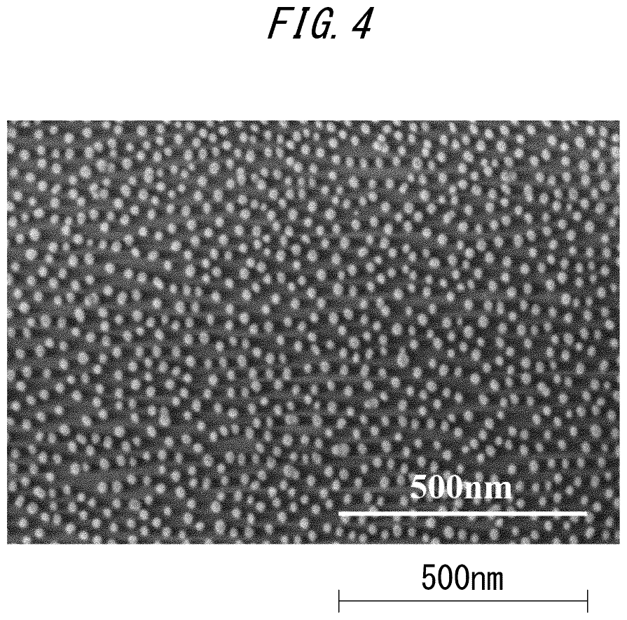

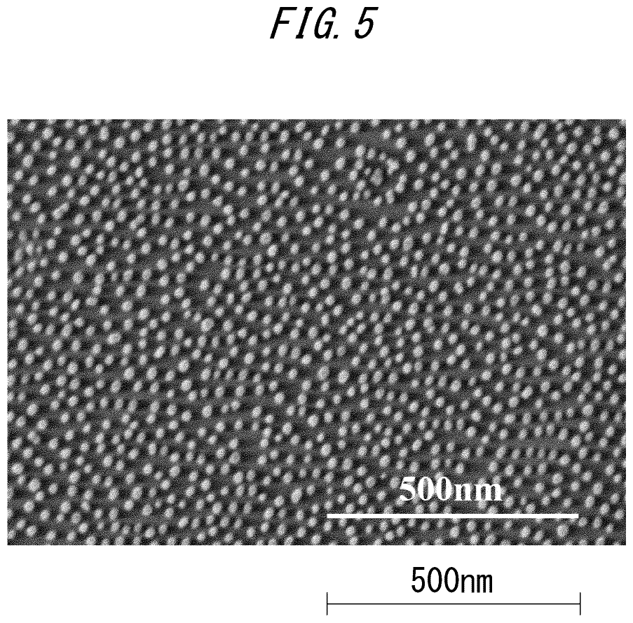

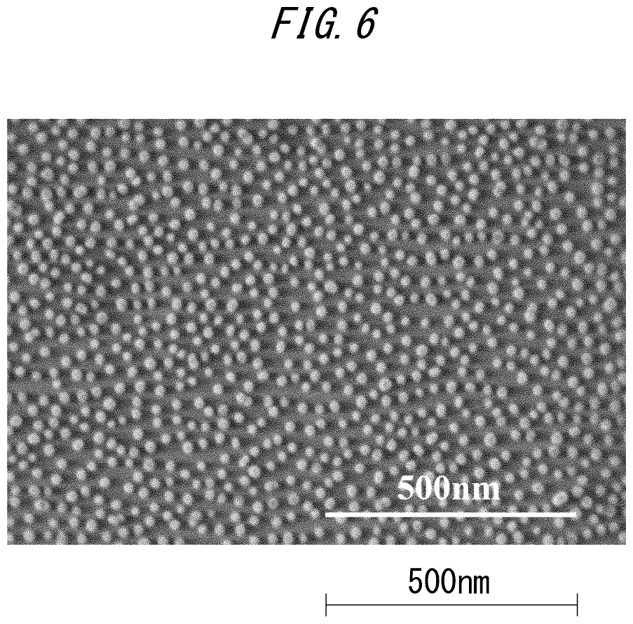

The observation points were 2 cm, 3 cm, and 4 cm from one end of the cylindrical device (three points spaced 1 cm apart in the axial direction of the cylindrical device), designated as points A, B, and C, respectively, and SEM images (magnification: 100,000 times) of points A to C were obtained. The SEM images were taken using a field emission scanning electron microscope (produced by Hitachi High-Tech Corporation, model: SU8000). FIG. 4 to FIG. 6 illustrate SEM images of these points A to C. From the image analysis results of these SEM images, it was confirmed that gold nanoparticles having an average value of particle size of 20 nm were arranged on the inner surface of the glass tube.

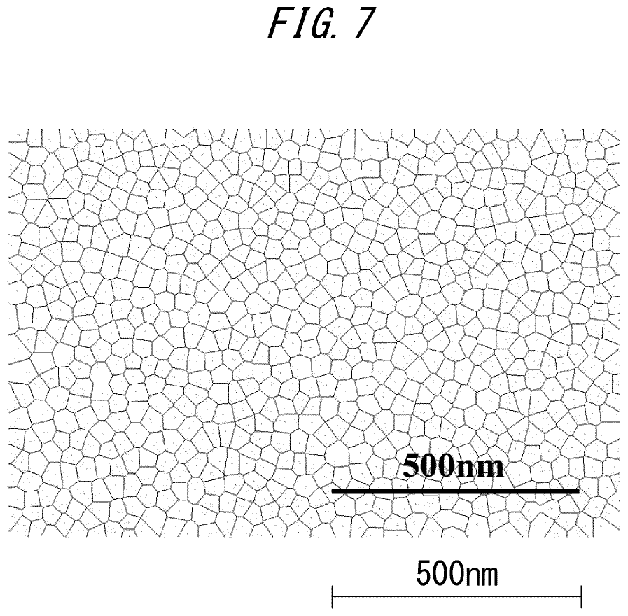

These SEM images were further subjected to Voronoi analysis, in which the SEM images were divided into Voronoi regions using the centers of gravity of the gold nanoparticles as sites. As an example of the result of the Voronoi analysis, a diagram illustrating the division state of the Voronoi regions at point A (hereinafter referred to as a Voronoi analysis diagram) is illustrated in FIG. 7.

Based on the results of this Voronoi analysis, the average value and standard deviation of the areas of the Voronoi regions (hereinafter sometimes referred to as the Voronoi area) in each SEM image (the average value and standard deviation of the areas of the Voronoi regions in three SEM images) were further determined. In addition, the average value of interparticle distance was calculated based on the Voronoi regions. Further, the average value of the interparticle surface distance was calculated based on the average value of interparticle distance and the average value of particle size of the gold nanoparticles. The results are listed in Table 1.

TABLE 1

| | | Standard | Average value of | | Average value of | Average value of |
|---|---|---|---|---|---|---|
| | Average value of | deviation of | interparticle | Average value of | interparticle | number of |
| | Voronoi area | Voronoi area | distance | particle size | surface distance | crystals generated |
| | (nm³) | (nm³) | (nm) | (nm) | (nm) | (number) |
| Example 1 | 1121 | 263 | 33 | 20 | 13 | 2.5 |
| Example 2 | 2613 | 1792 | 51 | 20 | 31 | 1.3 |
| Example 3 | 3986 | 680 | 63 | 20 | 43 | 0.5 |
| Example 4 | 3250 | 2122 | 57 | 20 | 37 | 0.8 |
| Comparative | — | — | — | — | — | 0 |
| Example 1 | | | | | | |

The average value of interparticle distance of the gold nanoparticles determined for each SEM image was approximately 33 nm, and no variation in the adsorption density (arrangement density of gold nanoparticles) was observed between observation points. That is, no variation in adsorption density was observed in the axial direction of the cylindrical device.

Next, a 50 mm length was cut out from one end of this cylindrical device to form a capillary for a counter-diffusion method, which was then used in a protein crystallization experiment.

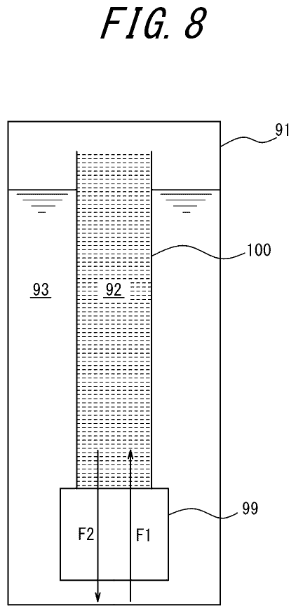

FIG. 8 illustrates an explanatory diagram of a protein crystallization experiment using a counter-diffusion method.

In this example, the protein crystallization experiment by a counter-diffusion method was carried out as follows. First, a protein solution 92 was filled into the cylindrical device 100 serving as a capillary, and the lower end of the capillary was closed with a gel layer 99. Then, the lower end of the capillary was immersed in a precipitant solution 93 (crystallization reagent). Specifically, the precipitant solution 93 was stored in a container 91, and the capillary was inserted into the container 91, and the lower end of the capillary together with the gel layer 99 was immersed in the precipitant solution 93 stored in the container 91. In this state, the protein solution 92 can diffuse through the gel layer 99 into the precipitant solution 93 outside the capillary (see diffusion flow F2), and the precipitant solution 93 can diffuse through the gel layer 99 into the protein solution 92 inside the capillary (see diffusion flow F1).

In this example, a lysozyme solution containing 20 mg/L of lysozyme and 600 mM (mmol/L) sodium chloride and 50 mM (mmol/L) acetic acid as a buffer solution, adjusted to a pH of about 4.5, was used as the protein solution.

As a precipitant solution (crystallization reagent), an acetate buffer solution containing 800 mM sodium chloride and 50 mM acetic acid and adjusted to a pH of about 4.5 was used.

The gel layer 99 was made of agarose gel, which is a porous material.

The crystallization experiment was carried out by leaving the mixture to stand for 6 weeks under temperature control at 20±0.5° C. Four sets of crystallization experiments were carried out simultaneously under the same conditions (that is, n=4).

Table 1 also indicates the results of the crystallization experiments. The “average value of number of crystals generated” listed in Table 1 was calculated by counting the number of crystals obtained for each set and calculating the average value (arithmetic mean value) of the four sets. As indicated in Table 1, in this example, an average of 2.5 crystals were obtained.

### Example 2

Example 2 differs from Example 1 in that the amount of methylol melamine crosslinking agent in the primer solution was decreased to 0.3 wt %. Otherwise, the cylindrical device was produced in the same way as for Example 1, and a crystallization experiment was carried out using this device.

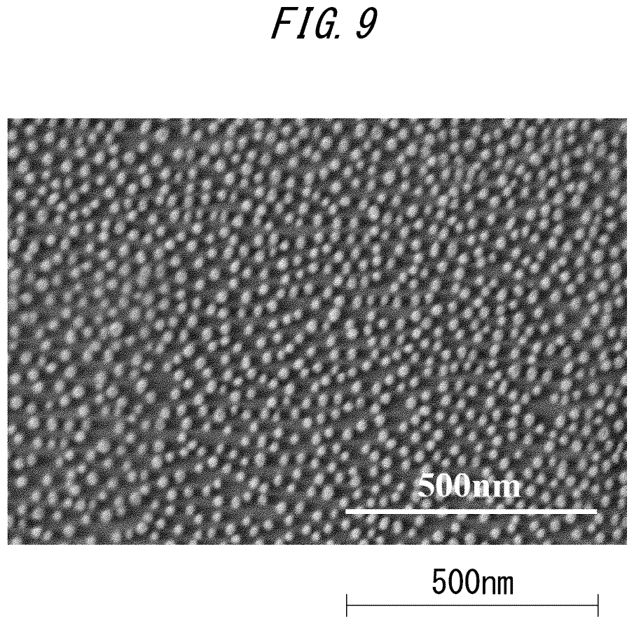

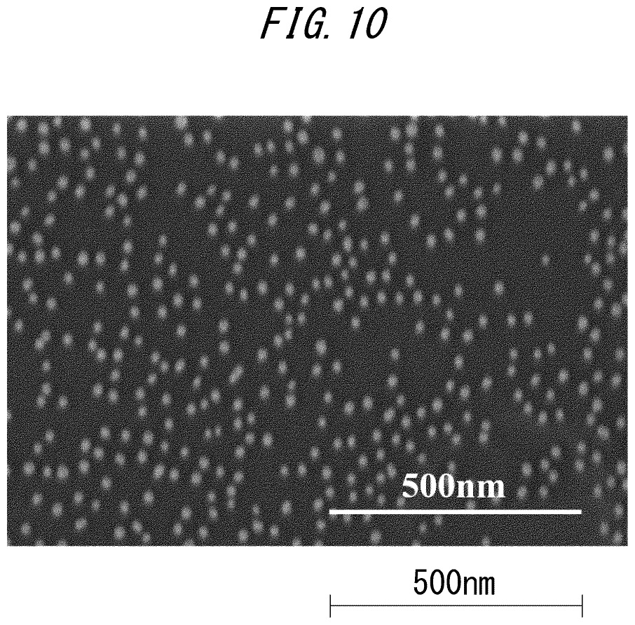

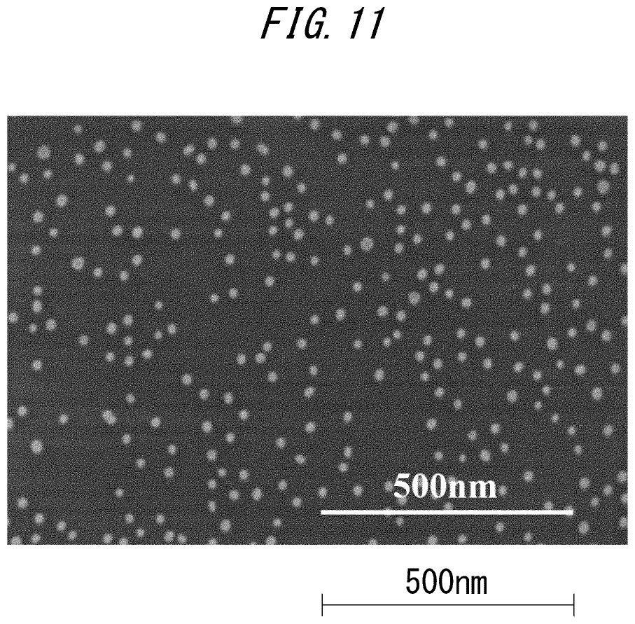

FIG. 9 to FIG. 11 illustrate SEM images of points A to C for the present example. Table 1 also lists the average value and standard deviation of the areas of the Voronoi regions in each SEM image in the present example, as well as the results of the crystallization experiment.

As indicated in Table 1, it was found that the standard deviation of the Voronoi areas in Example 2 was particularly large compared to Example 1, and the variation in the adsorption density of gold nanoparticles was also large. Further, it was found that the average value of the Voronoi areas was increased compared to Example 1, and the adsorption density of the gold nanoparticles was decreased. This result can also be seen from the SEM images illustrated in FIG. 9 to FIG. 11. The average value of number of crystals generated in the crystallization experiment was lower than in Example 1, which is thought to be due to the increase in the variation in the adsorption density of gold nanoparticles and the decrease in the adsorption density of gold nanoparticles.

### Example 3

Example 3 differs from Example 1 in that the amount of tetrachloroauric (III) acid in the gold colloid solution was decreased to 0.03 g/L. Otherwise, the cylindrical device was produced in the same way as for Example 1, and a crystallization experiment was carried out using this device.

Table 1 lists the average value and standard deviation of the areas of the Voronoi regions in each SEM image in the present example, as well as the results of the crystallization experiment.

As indicated in Table 1, it was found that in Example 3, the average value of the Voronoi areas was particularly increased compared to Example 1, and the adsorption density of gold nanoparticles was greatly decreased. In the present example, the average value of number of crystals generated in the crystallization experiment was smaller than in Examples 1 and 2. This is thought to be due to the significant decrease in the adsorption density of gold nanoparticles.

### Example 4

Example 4 differs from Example 1 in that the holding time when forming the metal structure was extended to 30 min and the replacement operation was only carried out once. Otherwise, the cylindrical device was produced in the same way as for Example 1, and a crystallization experiment was conducted using this device.

Table 1 lists the average value and standard deviation of the areas of the Voronoi regions in each SEM image in the present example, as well as the results of the crystallization experiment.

As indicated in Table 1, in Example 4, the average value of the Voronoi areas was increased and the standard deviation of the Voronoi areas was increased compared to Examples 1 and 2. That is, the adsorption density of the gold nanoparticles decreased, and the variation in the adsorption density of the gold nanoparticles increased. The average value of number of crystals generated in the crystallization experiment was lower than in Examples 1 and 2.

### Comparative Example 1

Comparative Example 1 differs from Example 1 in that the formation of the primer layer was omitted. Otherwise, the cylindrical device was produced in the same way as in Example 1, and a crystallization experiment was carried out using this device.

In Comparative Example 1, it was not possible to form a metal structure. This is thought to be due to the omission of the formation of the primer layer. Therefore, in Comparative Example 1, it was not possible to obtain the average value and standard deviation of the areas of the Voronoi regions. Table 1 also indicates the results of the crystallization experiment for the present comparative example.

In the present comparative example, no crystals were obtained in the crystallization experiment. This is thought to be because no metal structure was formed on the capillary.

As described above, when using the cylindrical device according to the present embodiment as a capillary for a counter-diffusion method, it was found that crystallization is facilitated in the counter-diffusion method when the average value of interparticle surface distance between adjacent metal particles in the metal structure is 3 nm or more and 90 nm or less, and preferably 10 nm or more and 50 nm or less. Further, it was found that when the standard deviation of the areas of the Voronoi regions is 200 nm² or more and 2000 nm² or less, crystallization is facilitated in the counter-diffusion method.

Further, it was found that crystallization is facilitated in the counter-diffusion method when the arithmetic mean of the areas of the Voronoi regions of the metal structure is 1000 nm² or more and 4000 nm² or less, and preferably 1000 nm² or more and 3300 nm² or less. Further, it was found that when the standard deviation of the areas of the Voronoi regions is 200 nm² or more and 2000 nm² or less, crystallization is facilitated in the counter-diffusion method. Further, it was found that when producing the cylindrical device

according to the present embodiment, forming a primer layer allows for the formation of a good metal structure. This has revealed that when the cylindrical device according to the present embodiment is used as a capillary for a counter-diffusion method, crystallization is facilitated.

As described above, it is possible to provide a cylindrical device in which crystallization by a counter-diffusion method is facilitated, a method of producing the cylindrical device, and a method of crystallizing a protein using the cylindrical device.

The embodiments disclosed herein are illustrative, and variations as appropriate within the scope of the present disclosure may be made without being limited to the disclosed embodiments.

### INDUSTRIAL APPLICABILITY

The present disclosure is applicable to a cylindrical device, a method of producing a cylindrical device, and a method of crystallizing a protein.

### REFERENCE SIGNS LIST

1: cylindrical body
2: metal structure
21: primer layer
3: metal particles
91: container
92 protein solution
93: precipitant solution
99: gel layer
F1 diffusion flow
F2: diffusion flow
L: interparticle distance
G: interparticle surface distance

1. A cylindrical device comprising:
a cylindrical body that has a long shape; and
a metal structure disposed on an inner surface of the cylindrical body, wherein
the metal structure includes metal particles arranged on the inner surface of the cylindrical body,
the metal particles have an average value of diameter of 5 nm or more and 50 nm or less when viewed in a direction perpendicular to the inner surface of the cylindrical body, and
an average value of interparticle surface distance between adjacent metal particles is 3 nm or more and 90 nm or less.

2. The cylindrical device according to claim 1, wherein the cylindrical body is made of glass.

3. The cylindrical device according to claim 1, wherein an inner diameter of the cylindrical body is 0.2 mm or more and 2 mm or less.

4. The cylindrical device according to claim 1, wherein when the metal structure is divided into Voronoi regions using the centers of gravity of the respective metal particles as sites, an average value of areas of the Voronoi regions is 1000 nm² or more and 4000 nm² or less.

5. The cylindrical device according to claim 1, wherein when the metal structure is divided into Voronoi regions using the centers of gravity of the respective metal particles as sites, a standard deviation of areas of the Voronoi regions is 200 nm² or more and 2000 nm² or less.

6. The cylindrical device according to claim 1, wherein
the cylindrical body is made of glass,
an inner diameter of the cylindrical body is 0.2 mm or more and 2 mm or less, and
when the metal structure is divided into Voronoi regions using the centers of gravity of the respective metal particles as sites, a standard deviation of areas of the Voronoi regions is 200 nm² or more and 2000 nm² or less.

7. The cylindrical device of claim 1, wherein the metal particles comprise gold.

8. The cylindrical device of claim 6, wherein the metal particles comprise gold.

9. The cylindrical device according to claim 1, wherein
the metal structure includes a primer layer formed on the inner surface of the cylindrical body, and
the metal particles are fixed to the inner surface of the cylindrical body via the primer layer.

10. The cylindrical device according to claim 2, wherein
the metal structure includes a primer layer formed on the inner surface of the cylindrical body, and
the metal particles are fixed to the inner surface of the cylindrical body via the primer layer.

11. The cylindrical device according to claim 3, wherein
the metal structure includes a primer layer formed on the inner surface of the cylindrical body, and
the metal particles are fixed to the inner surface of the cylindrical body via the primer layer.

12. The cylindrical device according to claim 4, wherein
the metal structure includes a primer layer formed on the inner surface of the cylindrical body, and
the metal particles are fixed to the inner surface of the cylindrical body via the primer layer.

13. The cylindrical device according to claim 5, wherein
the metal structure includes a primer layer formed on the inner surface of the cylindrical body, and
the metal particles are fixed to the inner surface of the cylindrical body via the primer layer.

14. The cylindrical device according to claim 6, wherein
the metal structure includes a primer layer formed on the inner surface of the cylindrical body, and
the metal particles are fixed to the inner surface of the cylindrical body via the primer layer.

15. The cylindrical device according to claim 7, wherein
the metal structure includes a primer layer formed on the inner surface of the cylindrical body, and
the metal particles are fixed to the inner surface of the cylindrical body via the primer layer.

16. The cylindrical device according to claim 8, wherein
the metal structure includes a primer layer formed on the inner surface of the cylindrical body, and
the metal particles are fixed to the inner surface of the cylindrical body via the primer layer.

17. A method of producing the cylindrical device according to claim 1, the method comprising:
a primer layer forming process of forming a primer layer containing methylol melamine or a methylol melamine derivative on the inner surface of the cylindrical body; and
a metal structure forming process of constructing the metal structure on the primer layer, wherein
the metal structure forming process includes a liquid contact process of maintaining a state in which a metal colloid solution is retained within the cylindrical body.

18. A method of producing the cylindrical device according to claim 16, the method comprising:
a primer layer forming process of forming a primer layer containing methylol melamine or a methylol melamine derivative on the inner surface of the cylindrical body; and
a metal structure forming process of constructing the metal structure on the primer layer, wherein
the metal structure forming process includes a liquid contact process of maintaining a state in which a metal colloid solution is retained within the cylindrical body.

19. The method of producing the cylindrical device according to claim 16, wherein a residence time in the liquid contact process is 5 min or more and 60 min or less.

20. A method of crystallizing a protein by a counter-diffusion method, comprising:
using the cylindrical device according to claim 1 as a capillary.
